(19) United States
(12) Patent Application Publication
(10) Pub. No.: US 2023/0119181 A1
(43) Pub. Date: Apr. 20, 2023

(54) Semiconductor Device and Method of Forming RDL Hybrid Interposer Substrate

(71) Applicant: STATS ChipPAC Pte. Ltd., Singapore (SG)

(72) Inventors: JongTae Kim, Incheon (KR); NamJu Cho, Gyeonggi-do (KR); HaengCheol Choi, Gyeonggi-do (KR)

(73) Assignee: STATS ChipPAC Pte. Ltd., Singapore (SG)

(21) Appl. No.: 17/451,166

(22) Filed: Oct. 18, 2021

(51) Int. Cl. H01L 23/367; H01L 23/498; H01L 23/552; H01L 25/065

(52) U.S. Cl. CPC H01L 23/3675; H01L 23/49833; H01L 23/552; H01L 25/0652

(57) ABSTRACT

A semiconductor device has a first substrate and a first electrical component disposed over the first substrate. The first electrical component has a second substrate, and redistribution layer formed over the second substrate. The first electrical component is disposed over the redistribution layer. The heat spreader is disposed over the first electrical component. A heat spreader is disposed over the first electrical component. The heat spreader has a first horizontal portion, second horizontal portion vertically offset from the first horizontal portion, and an angled portion connecting the first horizontal portion from the second horizontal portion. The second horizontal portion attaches to a surface of the first substrate proximate to a first side of the first electrical component. The heat spreader attaches to the first substrate proximate to a first side of the first electrical component and remains open proximate to a second side of the first electrical component.

### FIELD OF THE INVENTION

The present invention relates in general to semiconductor devices and, more particularly, to a semiconductor device and method of forming a redistribution layer (RDL) hybrid interposer substrate with a heat spreader making contact to the substrate around a first portion of the semiconductor device, while leaving open a second portion of the semiconductor device.

### BACKGROUND OF THE INVENTION

Semiconductor devices are commonly found in modern electronic products. Semiconductor devices perform a wide range of functions, such as signal processing, high-speed calculations, transmitting and receiving electromagnetic signals, controlling electronic devices, photo-electric, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Semiconductor devices are susceptible to heat from operation of the semiconductor die. Some semiconductor die, such as a microprocessor, operate at a high clock frequency and generate heat from rapid transistor switching. Other semiconductor devices, such as a power MOSFET, generate heat by conducting significant current. The semiconductor die is mounted to a substrate and the heat sink is typically mounted to an area of the substrate around the semiconductor die. A portion of the heat sink thermally contacts a thermal interface material (TIM) deposited on a top surface of the semiconductor die and another portion of the heat sink mechanically and thermally contacts the substrate, with another TIM layer, to transfer or dissipate the heat away from the semiconductor die and into the substrate. The mechanical and thermal contact or physical attachment of the heat sink on all sides of the semiconductor die adds manufacturing complexity and cost.

### BRIEF DESCRIPTION OF THE DRAWINGS

FIGS. 1a-1c illustrate a semiconductor wafer with a plurality of semiconductor die separated by a saw street;

FIGS. 2a-2d illustrate a process of forming a semiconductor package with a semiconductor die and interconnect substrate;

FIGS. 3a-3l illustrate a process of forming an RDL hybrid interposer substrate with a reduced heat spreader attachment arrangement;

FIG. 4 illustrates an RDL hybrid interposer substrate with a reduced shielding layer attachment arrangement;

FIG. 5 illustrates another embodiment of the RDL hybrid interposer substrate with a reduced heat spreader attachment and electrical component under the substate;

FIG. 6 illustrates another embodiment of the RDL hybrid interposer substrate with a reduced heat spreader attachment and electrical component over the substate;

FIGS. 7a-7b illustrate another embodiment of the RDL hybrid interposer substrate with a reduced heat spreader attachment and finger molding; and

FIG. 8 illustrates a printed circuit board (PCB) with different types of packages mounted to a surface of the PCB.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are mounted to a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

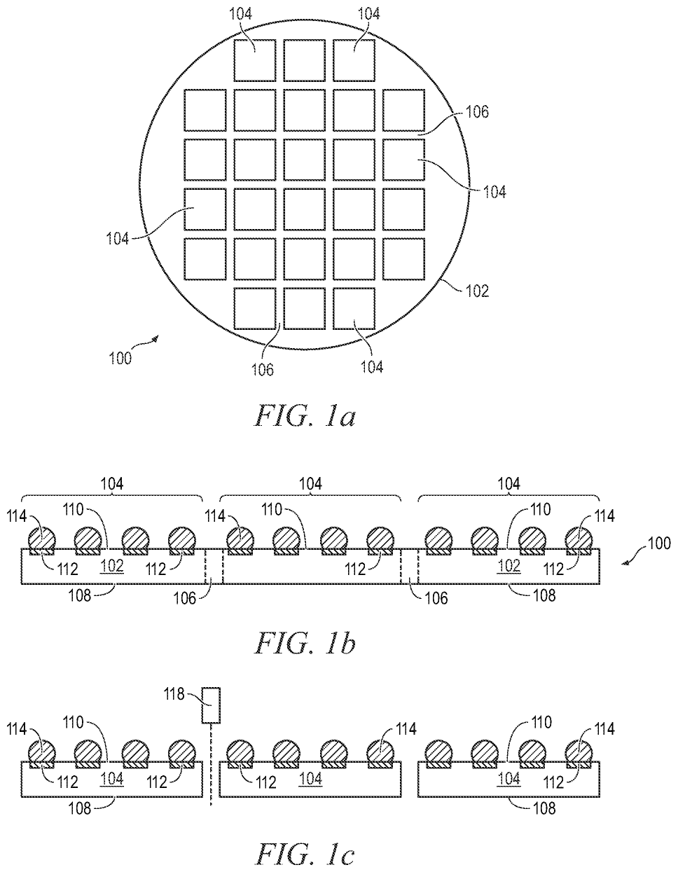

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

FIG. 1B shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 110 to implement analog circuits or digital circuits, such as digital signal processor (DSP), application specific integrated circuits (ASIC), memory, or other signal processing circuit. Semiconductor die 104 may also contain IPDs, such as inductors, capacitors, and resistors, for RF signal processing.

An electrically conductive layer 112 is formed over active surface 110 using PVD, CVD, electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110.

An electrically conductive bump material is deposited over conductive layer 112 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 112 using a suitable attachment or bonding process. In one embodiment, the bump material is reflowed by heating the material above its melting point to form balls or bumps 114. In one embodiment, bump 114 is formed over an under bump metallization (UBM) having a wetting layer, barrier layer, and adhesive layer. Bump 114 can also be compression bonded or thermocompression bonded to conductive layer 112. Bump 114 represents one type of interconnect structure that can be formed over conductive layer 112. The interconnect structure can also use bond wires, conductive paste, stud bump, micro bump, or other electrical interconnect.

In FIG. 1c, semiconductor wafer 100 is singulated through saw street 106 using a saw blade or laser cutting tool 118 into individual semiconductor die 104. The individual semiconductor die 104 can be inspected and electrically tested for identification of known good die or unit (KGD/KGU) post singulation.

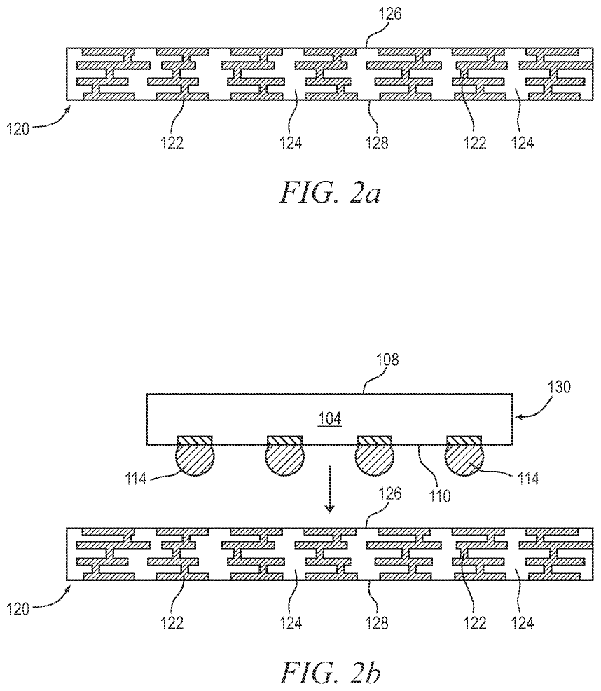

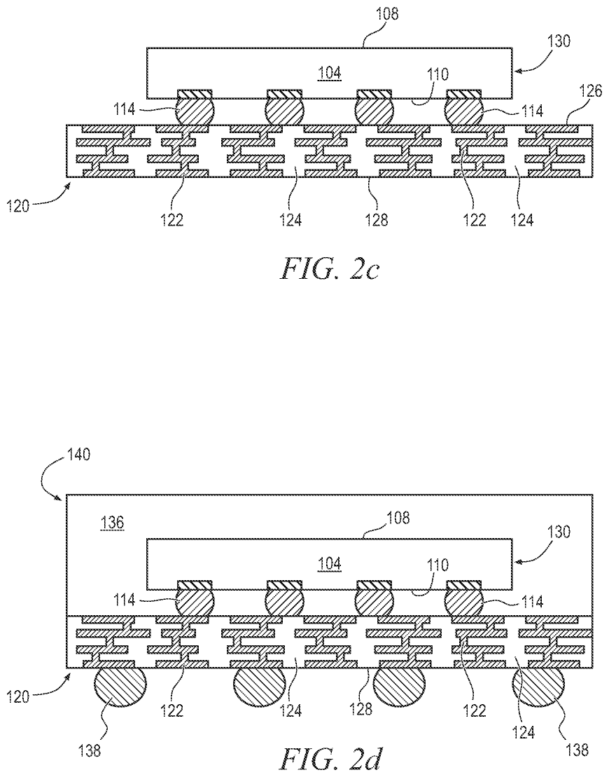

FIGS. 2a-2d illustrate a process of forming a semiconductor package with semiconductor die and interconnect substrate. FIG. 2a shows a cross-sectional view of interconnect substrate 120 including conductive layers 122 and insulating layer 124. Conductive layer 122 can be one or more layers of Al, Cu, Sn, Ni, Au, Ag, or other suitable electrically conductive material. Conductive layer 122 provides horizontal electrical interconnect across substrate 120 and vertical electrical interconnect between top surface 126 and bottom surface 128 of substrate 120. Portions of conductive layer 122 can be electrically common or electrically isolated depending on the design and function of semiconductor die 104 and other electrical components. Insulating layer 124 contains one or more layers of silicon dioxide (SiO2), silicon nitride (Si3N4), silicon oxynitride (SiON), tantalum pentoxide (Ta2O5), aluminum oxide (Al2O3), solder resist, polyimide, benzocyclobutene (BCB), polybenzoxazoles (PBO), and other material having similar insulating and structural properties. Insulating layer 124 provides isolation between conductive layers 122.

In FIGS. 2b-2c, electrical component 130 is mounted to surface 126 of interconnect substrate 120 and electrically and mechanically connected to conductive layers 122. Electrical component 130 is positioned over substrate 120 using a pick and place operation. For example, electrical component 130 can be semiconductor die 104 from FIG. 1c with active surface 110 and bumps 114 oriented toward surface 126 of substrate 120. Alternatively, electrical component 130 can include other semiconductor die, semiconductor package, surface mount device, discrete electrical device, discrete transistor, diode, or IPD. Electrical component 130 is mounted to interconnect substrate 120, as shown in FIG. 2c, with bumps 114 making mechanical and electrical connection to conductive layer 122.

In FIG. 2d, encapsulant or molding compound 136 is deposited over and around electrical component 130 and surface 126 of interconnect substrate 120 using a paste printing, compressive molding, transfer molding, liquid encapsulant molding, vacuum lamination, spin coating, or other suitable applicator. Encapsulant 136 can be polymer composite material, such as epoxy resin with filler, epoxy acrylate with filler, or polymer with proper filler. Encapsulant 136 is non-conductive, provides structural support, and environmentally protects the semiconductor device from external elements and contaminants.

An electrically conductive bump material is deposited over conductive layer 122 on surface 128 of interconnect substrate 120 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 122 using a suitable attachment or bonding process. In one embodiment, the bump material is reflowed by heating the material above its melting point to form balls or bumps 138. In one embodiment, bump 138 is formed over a UBM having a wetting layer, barrier layer, and adhesive layer. Bump 138 can also be compression bonded or thermocompression bonded to conductive layer 122. Bump 138 represents one type of interconnect structure that can be formed over conductive layer 122. The interconnect structure can also use bond wires, conductive paste, stud bump, micro bump, or other electrical interconnect.

Semiconductor package 140 contains encapsulated electrical component 130 mounted to interconnect substrate 120 with external bumps 138. Semiconductor package 140 can be inspected and electrically tested for identification of KGU.

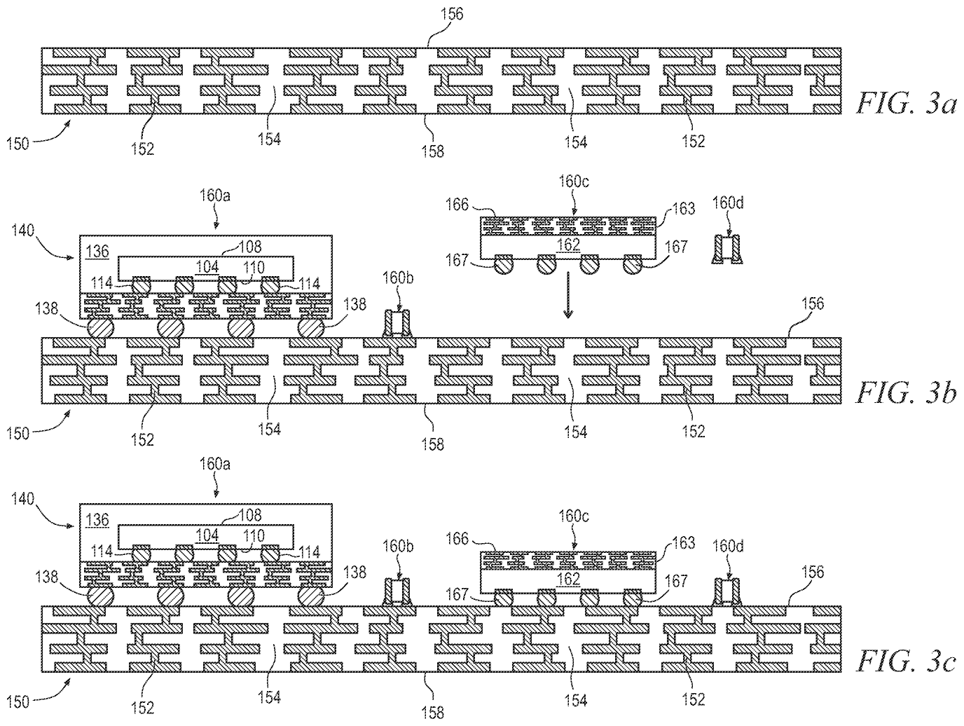

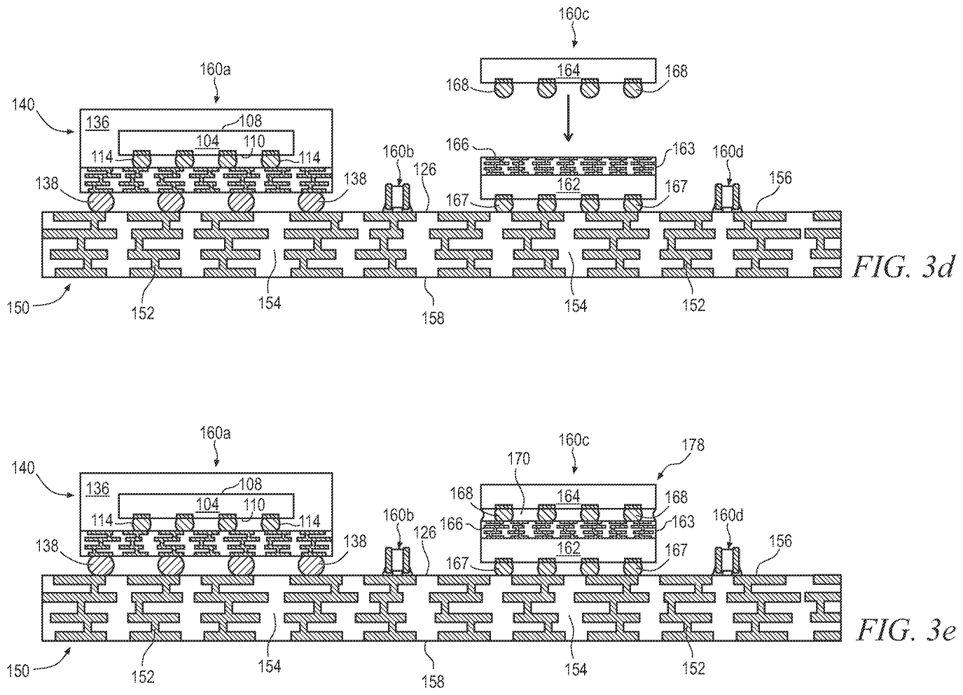

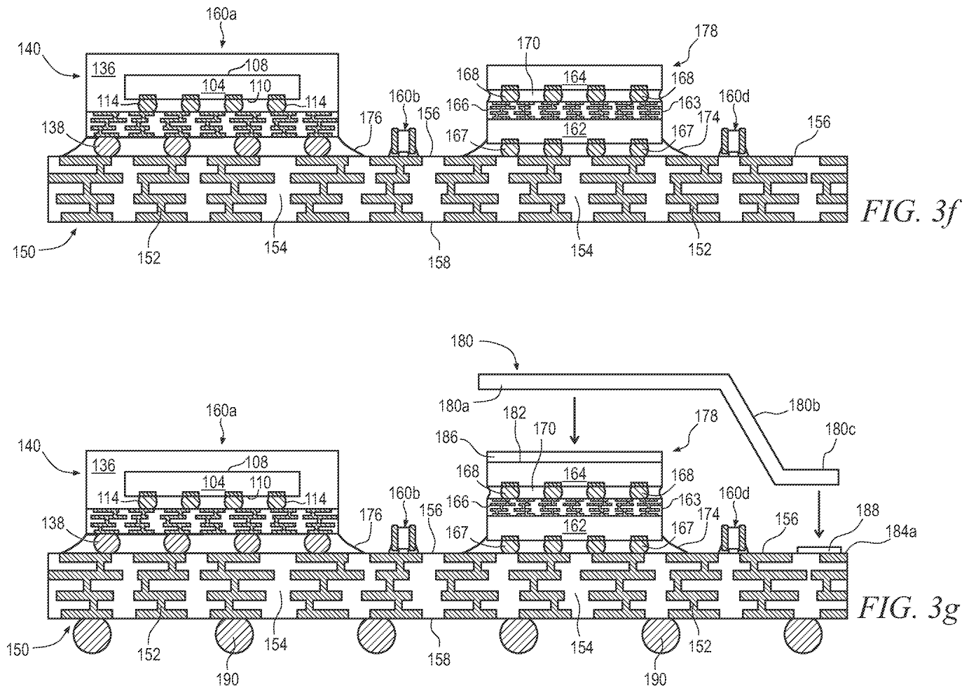

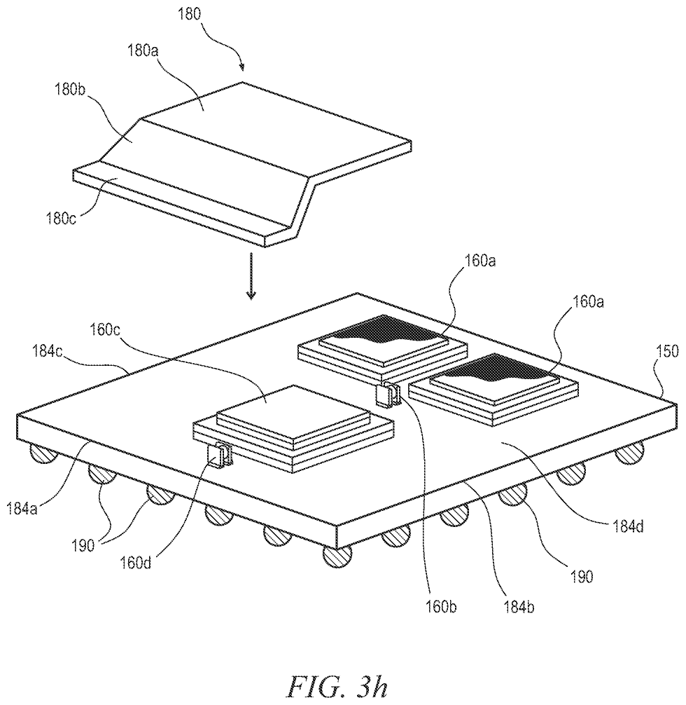

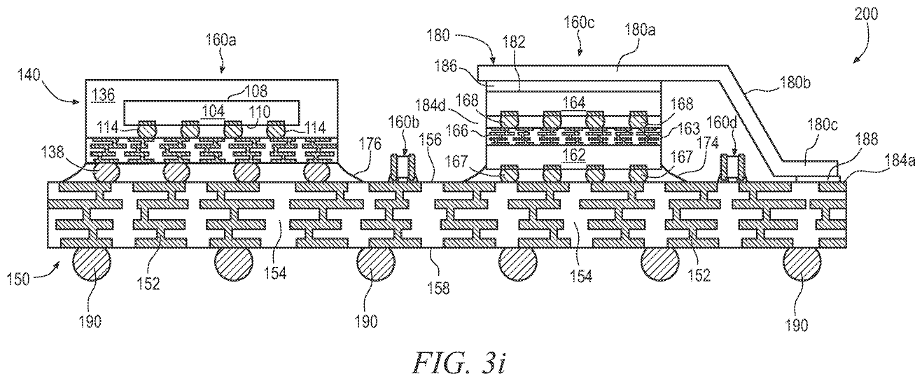

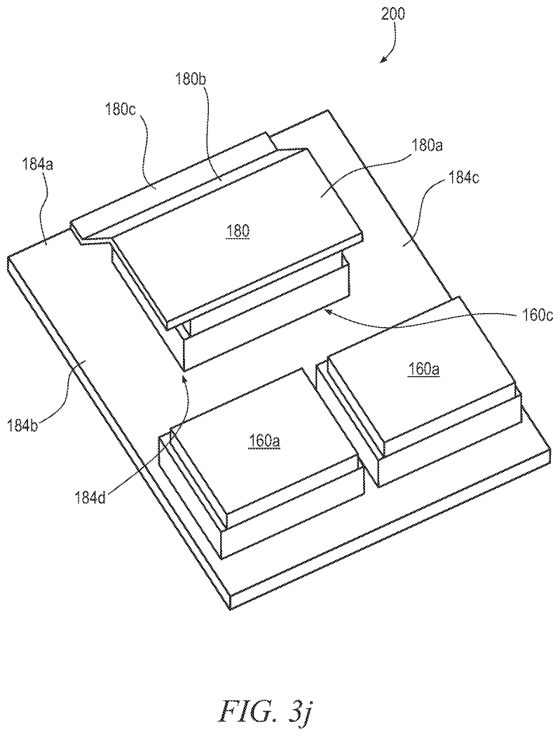

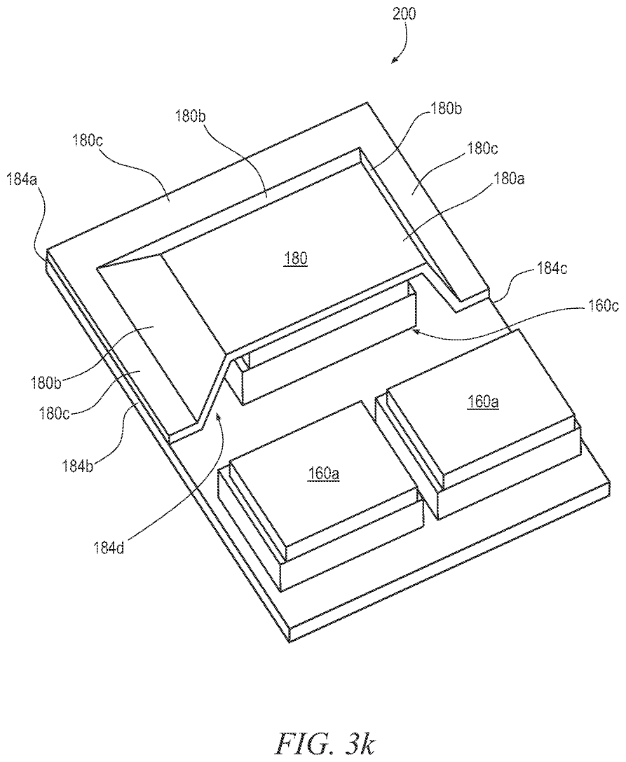

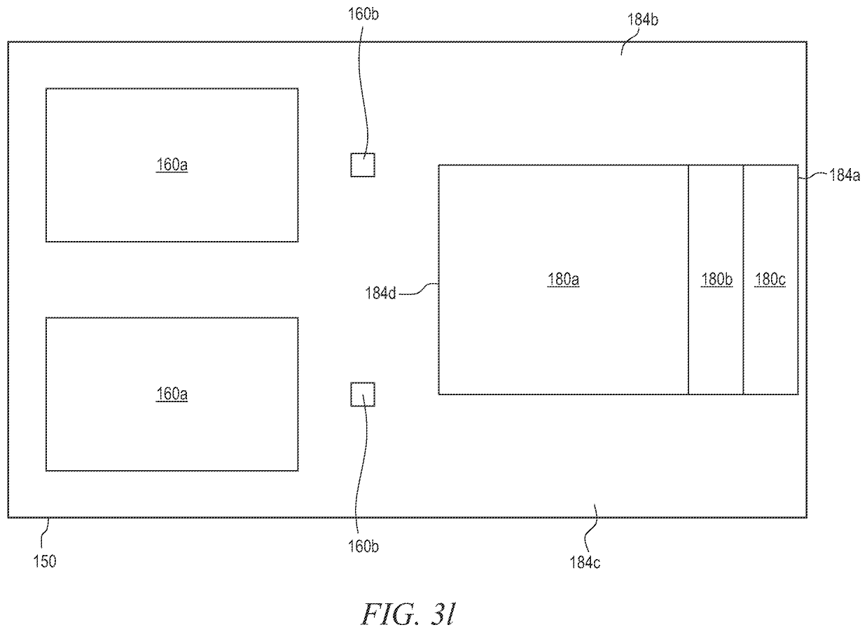

FIGS. 3a-3l illustrate a process of forming an RDL hybrid interposer substrate with a heat spreader making contact to the substrate around a first portion of the semiconductor device, while leaving open a second portion of the semiconductor device. FIG. 3a shows a cross-sectional view of interconnect substrate 150 including conductive layers 152 and insulating layer 154. Conductive layer 152 can be one or more layers of Al, Cu, Sn, Ni, Au, Ag, or other suitable electrically conductive material. Conductive layer 152 provides horizontal electrical interconnect across substrate 150 and vertical electrical interconnect between top surface 156 and bottom surface 158 of substrate 150. Portions of conductive layer 152 can be electrically common or electrically isolated depending on the design and function of the electrical components mounted thereto. Insulating layer 154 contains one or more layers of SiO2, Si3N4, SiON, Ta2O5, Al2O3, solder resist, polyimide, BCB, PBO, and other material having similar insulating and structural properties. Insulating layer 154 provides isolation between conductive layers 152.

In FIG. 3b, a plurality of electrical components 160a-160d is mounted to surface 156 of interconnect substrate 150 and electrically and mechanically connected to conductive layers 152. Electrical components 160a-160d are each positioned over substrate 150 using a pick and place operation. For example, electrical component 160a can be semiconductor package 140 from FIG. 2d with bumps 138 oriented toward surface 156 of substrate 150 and electrically connected to conductive layer 152. Electrical components 160b and 160d can be discrete semiconductor devices, such as a transistor, diode, resistor, capacitor, inductor, or other discrete devices with electrical terminals electrically connected to conductive layer 152. Electrical component 160d can be an RDL hybrid interposer including interconnect substrate 162 and RDL 163 having conductive layers 166 separated by insulating material formed on the interconnect substrate. Bumps 167 are formed on a surface of interconnect substrate 162 opposite RDL 163. RDL hybrid interposer 162-163 is disposed over interconnect substrate 150 with bumps 167 oriented toward surface 156. Alternatively, electrical components 160a-160d can include other semiconductor die, semiconductor package, interposer, surface mount device, discrete electrical device, discrete transistor, diode, or IPD. Electrical components 160a-160d are mounted to interconnect substrate 120, as shown in FIG. 3c, with bumps 138, 167, and terminals making mechanical and electrical connection to conductive layer 152.

In FIG. 3d, electrical component 164 is positioned over RDL hybrid interposer substrate 162-163 using a pick and place operation. Electrical component 164 can be made similar to semiconductor die 104 from FIG. 1c, with a different format and function, and bumps 168 oriented toward RDL 163. Alternatively, electrical component 164 can include other semiconductor die, semiconductor package, surface mount device, discrete electrical device, discrete transistor, diode, or IPD. Electrical component 164 is mounted to RDL hybrid interposer substrate 162-163, as shown in FIG. 3e, with bumps 168 making mechanical and electrical connection to conductive layer 166.

Semiconductor package 178 contains electrical component 164 mounted to RDL hybrid interposer substrate 162-163 with bumps 168. Semiconductor package 178 is mounted to interconnect substrate with bumps 167 making mechanical and electrical connection to conductive layer 152. Semiconductor package 178 can be inspected and electrically tested for identification of KGU. An underfill material 170, such as epoxy resin, is deposited between RDL 163 and electrical component 164. Underfill material 170 is non-conductive, provides structural support, and environmentally protects semiconductor package 178 from external elements and contaminants.

In FIG. 3f, underfill material 174, such as epoxy resin, is deposited between substrate 162 and substrate 150 and around bumps 167. Underfill material 176, such as epoxy resin, is deposited between interconnect substrate 120 and substrate 150 and around bumps 138. Underfill material 174, 176 are non-conductive, provides structural support, and environmentally protects the semiconductor device from external elements and contaminants.

In FIG. 3g, cover 180 is disposed over semiconductor package 178 and interconnect substrate 150. In one embodiment, cover 180 is a heat spreader or heat sink including a first horizontal portion 180a, angled portion 180b, and second horizontal portion 180c vertically offset from the first horizontal portion by the angled portion. Note that semiconductor package 140 is disposed on substrate 150 away from a footprint of heat spreader 180. Electrical component 164 may generate significant heat as a power transistor, transmitter, or high frequency digital circuit. For example, a microprocessor operates at a high clock frequency and generates heat from rapid transistor switching. The excess heat must be dissipated for proper operation of electrical component 164. Heat spreader 180 can be one or more layers of Al, Cu, Sn, Ni, Au, Ag, or other suitable conductive material. A thermal interface material (TIM) 186 is deposited on surface 182 of electrical component 164. TIM 186 is deposited as a soft, compliant material and cures to a hard material with high adhesion properties. In one embodiment, TIM 186 is an adhesive with filler containing alumina (Al2O3), Al, Ag, or aluminum zinc oxide and a thermal conductivity of 1.9-11 W/m.K. TIM 186 is cured for 30-120 minutes at 120-150° C. with a post-cure Young's modulus of 0.036-0.075 Gpa. TIM 188 is deposited over surface 156 at the mounting point of second horizontal portion 180c along side surface 184a of substrate 150.

An electrically conductive bump material is deposited over conductive layer 152 on surface 158 of interconnect substrate 150 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 152 using a suitable attachment or bonding process. In one embodiment, the bump material is reflowed by heating the material above its melting point to form balls or bumps 190. In one embodiment, bump 190 is formed over a UBM having a wetting layer, barrier layer, and adhesive layer. Bump 190 can also be compression bonded or thermocompression bonded to conductive layer 152. Bump 190 represents one type of interconnect structure that can be formed over conductive layer 152. The interconnect structure can also use bond wires, conductive paste, stud bump, micro bump, or other electrical interconnect.

FIG. 3h is a perspective view of heat spreader 180 disposed over semiconductor package 178 and interconnect substrate 150. In particular, heat spreader 180 is attached to a first mounting surface on substrate 150 (e.g., side surface 184a), and/or a second mounting surface on substrate 150 (e.g., side surface 184b), and/or a third mounting surface on substrate 150 (e.g., side surface 184c). Heat spreader 180 is attached to at least one mounting surface (e.g., 184a) on substrate 150, and may be attached to two additional mounting surfaces (e.g., 184b, 184c). Heat spreader 180 can be open and non-attached along side 184d of substrate 150. In the case of FIG. 3h, heat spreader 180 is attached along side surface 184a and open along three sides 184b-184d.

FIG. 3i shows horizontal portion 180a of heat spreader 180 in thermal contact with TIM 186 and surface 182 of electrical component 164. During operation of electrical component 164, heat is dissipated from surface 182, through TIM 186, along horizontal portion 180a, down angled portion 180b, to horizontal portion 180c. Horizontal portion 180c makes thermal contact to TIM 188 and substrate 150 to route and dissipate the excess heat to the substrate.

Semiconductor assembly 200 contains electrical components 160a-160d mounted to interconnect substrate 150 with a heat spreader making contact to the substrate around a first portion of semiconductor package 178, while leaving open a second portion of the semiconductor package. Semiconductor assembly 200 can be inspected and electrically tested for identification of KGU.

FIG. 3j is a perspective view of semiconductor assembly 200 with heat spreader 180 mounted to interconnect substrate 150 over semiconductor package 178. Heat generated by electrical component 164 is transferred through surface 182, through TIM 186, along horizontal portion 180a, down angled portion 180b, to horizontal portion 180c. The horizontal portions 180c making thermal contact to TIM 188 route the excess heat to substrate 150. For example, if heat spreader 180 is attached to substrate 150 along side surface 184a, heat is dissipated into substrate 150 along one side surface 184a of the heat spreader and substrate. In this case, heat spreader 180 is open and non-attached along sides 184b-184d of substrate 150 to simplify manufacturing and save cost.

FIG. 3k is a perspective view of an alternate embodiment of semiconductor assembly 200 with heat spreader 180 mounted to interconnect substrate 150 over semiconductor package 178. Heat generated by electrical component 164 is transferred through surface 182, through TIM 186, along horizontal portion 180a, down angled portion 180b, to horizontal portion 180c. The horizontal portions 180c making thermal contact to TIM 188 route the excess heat to substrate 150. For example, if heat spreader 180 is attached to substrate 150 along side surface 184a, side surface 184b, and side surface 184c, heat is dissipated into substrate 150 along three side surfaces 184a-184c of the heat spreader and substrate. In this case, heat spreader 180 is open and non-attached along side 184d of substrate 150 to simplify manufacturing and save cost.

FIG. 3l is a top view of semiconductor assembly 200 with heat spreader 180 mounted to interconnect substrate 150 over semiconductor package 178. Heat generated by electrical component 164 is transferred through surface 182, through TIM 186, along horizontal portion 180a, down angled portion 180b, to horizontal portion 180c. The horizontal portions 180c making thermal contact to TIM 188 and substrate 150 to route and dissipate the excess heat to the substrate. For example, if heat spreader 180 is attached to substrate 150 along side surface 184a, heat is dissipated into substrate 150 along one side surface 184a of the heat spreader. In this case, heat spreader 180 is open and non-attached along sides 184b-184d of substrate 150, including an area proximate to semiconductor packages 160a, to simplify manufacturing and save cost. Semiconductor package 140 is disposed on substrate 150 away from a footprint of heat spreader 180.

In another embodiment, electrical components 160a-160d may contain IPDs that are susceptible to or generate EMI, RFI, harmonic distortion, and inter-device interference. For example, the IPDs contained within electrical components 160a-160d provide the electrical characteristics needed for high-frequency applications, such as resonators, high-pass filters, low-pass filters, band-pass filters, symmetric Hi-Q resonant transformers, and tuning capacitors. In another embodiment, electrical components 160a-160d contain digital circuits switching at a high frequency, which could interfere with the operation of IPDs in the semiconductor package.

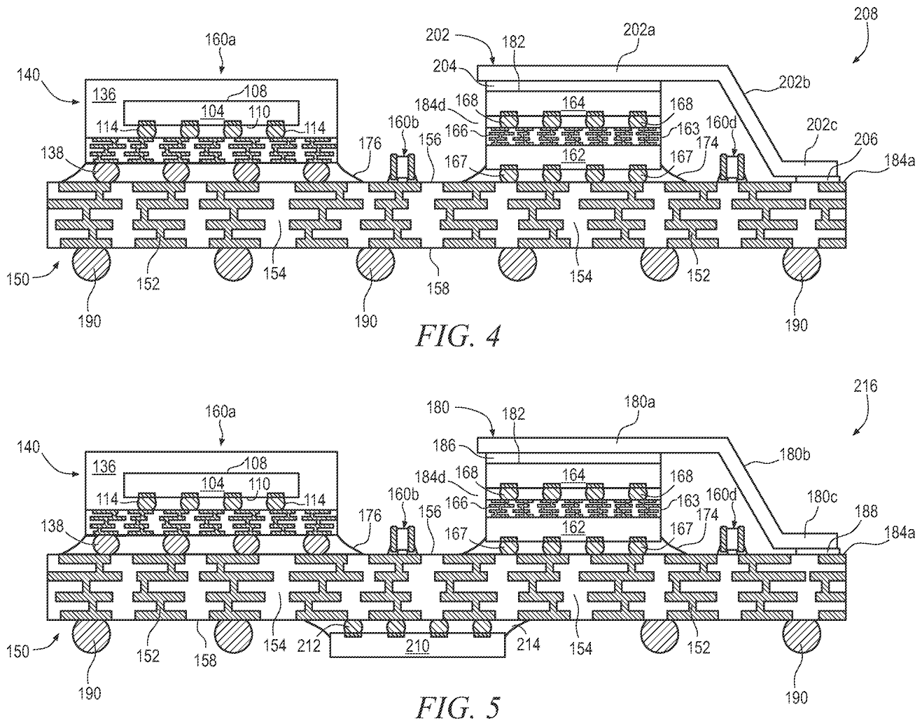

In FIG. 4, cover 202 is disposed over semiconductor package 178 and interconnect substrate 150. In one embodiment, cover 202 is an electromagnetic shielding layer including a first horizontal portion 202a, angled portion 202b, and second horizontal portion 202c vertically offset from the first horizontal portion by the angled portion. Shielding layer 202 can be one or more layers of Al, Cu, Sn, Ni, Au, Ag, or other suitable conductive material. Alternatively, shielding layer 202 can be carbonyl iron, stainless steel, nickel silver, low-carbon steel, silicon-iron steel, foil, conductive resin, carbon-black, aluminum flake, and other metals and composites capable of reducing or inhibiting the effects of EMI, RFI, and other inter-device interference. Electrical component 164 may generate or be susceptible to EMI, RFI, harmonic distortion, and inter-device interference. Electromagnetic shielding layer 202 discharges the EMI, RFI, harmonic distortion, and inter-device interference through substrate 150 to ground for proper operation of electrical component 164.

Horizontal portion 202a of shielding layer 202 is mounted to surface 182 of electrical component 164 with adhesive 204. Horizontal portion 202c of shielding layer 202 is mounted to surface 156 of interconnect substrate 150 with adhesive 206. Angled portion 202b connects horizontal portion 202a and horizontal portion 202c. The EMI, RFI, harmonic distortion, and inter-device interference is transferred through surface 182, along horizontal portion 202a, down angled portion 202b, along horizontal portion 202c, to ground in substrate 150. For example, if electromagnetic shielding layer 202 is attached to substrate 150 along side surface 184a, then EMI, RFI, harmonic distortion, and inter-device interference is grounded into substrate 150 along one side surface 184a of the shielding layer and substrate, similar to FIG. 3j. Electromagnetic shielding layer 202 is open and non-attached along side 184b-184d of substrate 150 to simplify manufacturing and save cost. The top view of electromagnetic shielding layer 202 on semiconductor assembly 208 is similar to FIG. 31. Alternatively, if electromagnetic shielding layer 202 is attached to substrate 150 along three side surfaces 184a-184c, then EMI, RFI, harmonic distortion, and inter-device interference is grounded into substrate 150 along three side surface 184a-184c of the shielding layer and substrate, similar to FIG. 3k. Electromagnetic shielding layer 202 is open and non-attached along side 184d of substrate 150 to simplify manufacturing and save cost. Semiconductor package 140 is disposed on substrate 150 away from a footprint of electromagnetic shielding layer 202.

Semiconductor package 140 is disposed on substrate 150 away from a footprint of electromagnetic shielding layer 202.

In another embodiment as shown in FIG. 5, similar to semiconductor assemblies 200 and 208, electrical component 210 is positioned over surface 158 of interconnect substrate 150 using a pick and place operation. Electrical component 210 can be made similar to semiconductor die 104 from FIG. 1c, with a different format and function, and bumps 212 oriented toward surface 158 of interconnect substrate 150. Alternatively, electrical component 210 can include other semiconductor die, semiconductor package, surface mount device, discrete electrical device, discrete transistor, diode, or IPD. Electrical component 210 is mounted to surface 158 of interconnect substrate 150 with bumps 212 making mechanical and electrical connection to conductive layer 152. An underfill material 214, such as epoxy resin, is deposited between interconnect substrate 150 and electrical component 210. Underfill material 214 is non-conductive, provides structural support, and environmentally protects semiconductor package 216 from external elements and contaminants.

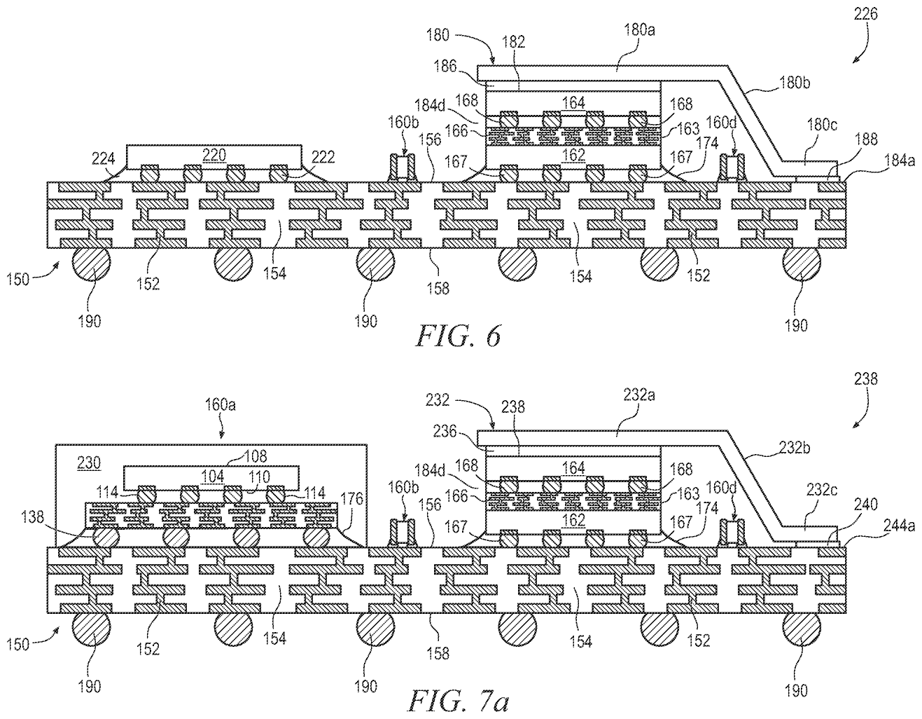

In another embodiment as shown in FIG. 6, similar to semiconductor assemblies 200 and 208, electrical component 220 is positioned over surface 156 of interconnect substrate 150 using a pick and place operation. Electrical component 220 can be in addition to, or in lieu of, semiconductor package 140, from FIG. 3i. Electrical component 220 can be made similar to semiconductor die 104 from FIG. 1c, with a different format and function, and bumps 222 oriented toward surface 156 of interconnect substrate 150. Alternatively, electrical component 220 can include other semiconductor die, semiconductor package, surface mount device, discrete electrical device, discrete transistor, diode, or IPD. Electrical component 220 is mounted to surface 156 of interconnect substrate 150 with bumps 222 making mechanical and electrical connection to conductive layer 152. An underfill material 224, such as epoxy resin, is deposited between interconnect substrate 150 and electrical component 220. Underfill material 224 is non-conductive, provides structural support, and environmentally protects semiconductor assembly 226 from external elements and contaminants.

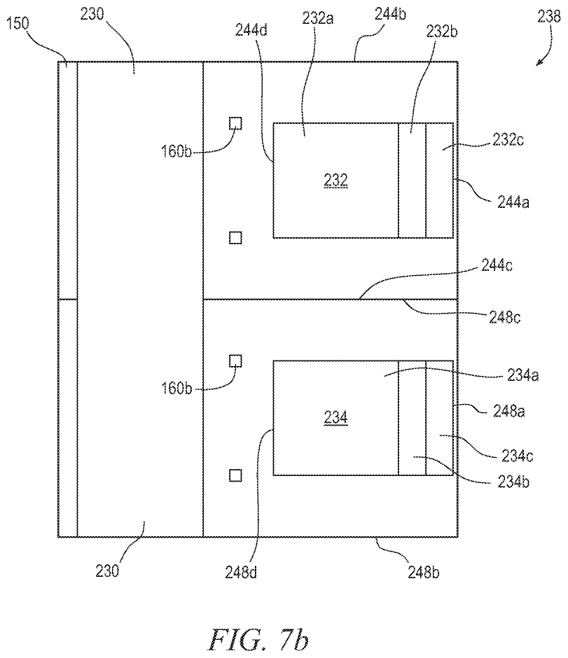

In another embodiment as shown in FIGS. 7a-7b, similar to semiconductor assemblies 200 and 208, encapsulant or molding compound 230 is deposited over electrical component 160a and surface 126 of interconnect substrate 120 using a paste printing, compressive molding, transfer molding, liquid encapsulant molding, vacuum lamination, spin coating, or other suitable applicator. In particular, encapsulant 230 covers multiple electrical components 160a, as shown in FIG. 7b, also known as finger molding. Encapsulant 230 can be polymer composite material, such as epoxy resin with filler, epoxy acrylate with filler, or polymer with proper filler. Encapsulant 230 is non-conductive, provides structural support, and environmentally protects the semiconductor device from external elements and contaminants.

Covers 232 and 234 are disposed over semiconductor packages 178 and interconnect substrate 150. In one embodiment, cover 232 is a heat spreader or heat sink including a first horizontal portion 232a, angled portion 232b, and second horizontal portion 232c vertically offset from the first horizontal portion by the angled portion. Cover 234 is a heat spreader or heat sink including a first horizontal portion 234a, angled portion 234b, and second horizontal portion 234c vertically offset from the first horizontal portion by the angled portion. Electrical component 164 in semiconductor package 178 may generate significant heat as a power transistor, transmitter, or high frequency digital circuit. For example, a microprocessor operates at a high clock frequency and generates heat from rapid transistor switching. The excess heat must be dissipated for proper operation of electrical component 164. Heat spreaders 232 and 234 can each be one or more layers of Al, Cu, Sn, Ni, Au, Ag, or other suitable conductive material. TIM 236 is deposited on surface 238 of electrical component 164. TIM 236 is deposited as a soft, compliant material and cures to a hard material with high adhesion properties. In one embodiment, TIM 236 is an adhesive with filler containing Al2O3, Al, Ag, or aluminum zinc oxide and a thermal conductivity of 1.9-11 W/m.K. TIM 236 is cured for 30-120 minutes at 120-150° C. with a post-cure Young's modulus of 0.036-0.075 Gpa. TIM 240 is deposited over surface 156 at the mounting surface of heat spreader 232, 234 along side surface 244a of substrate 150.

Heat spreaders 232 and 234 each follow the views of FIGS. 3h-3j, 3l, or follows the view of FIG. 3k, as disposed over semiconductor package 178 and attached to interconnect substrate 150. In particular, heat spreader 232 is attached to a first mounting surface on substrate 150 (e.g., side surface 244a), and/or a second mounting surface on substrate 150 (e.g., side surface 244b), and/or a third mounting surface on substrate 150 (e.g., side surface 244c). Heat spreader 234 is attached to a first mounting surface on substrate 150 (e.g., side surface 248a), and/or a second mounting surface on substrate 150 (e.g., side surface 248b), and/or a third mounting surface on substrate 150 (e.g., side surface 248c). Heat spreaders 232, 234 are each attached to at least one mounting surface (e.g., side surfaces 244a, 248a) on substrate 150, and may be attached to two additional mounting surfaces (e.g., side surfaces 244b, 248b, 244c, 248c). Heat spreader 232 can be open and non-attached along side 244d of substrate 150. Heat spreader 234 can be open and non-attached along side 248d of substrate 150.

FIG. 7a shows horizontal portion 232a of heat spreader 232 in thermal contact with TIM 236 and surface 238 of electrical component 164. During operation of electrical component 164, heat is dissipated from surface 238, through TIM 236, along horizontal portion 232a, down angled portion 232b, to horizontal portion 232c. Horizontal portion 232c makes thermal contact to TIM 240 to route the excess heat to substrate 150. Heat spreader 234 follows a similar explanation.

In FIG. 7b, heat generated by electrical component 164 is transferred through surface 238, through TIM 236, along horizontal portion 232a, down angled portion 232b, along horizontal portion 232c, through TIM 240 to dissipate the excess heat in substrate 150. For example, if heat spreader 232 is attached to substrate 150 along side surface 244a, heat is dissipated into substrate 150 along one side surface 244a of the heat spreader and substrate. Heat spreader 234 follows a similar explanation. Again, heat spreaders 232 and 234 are open and non-attached along sides 244b-244d, 248b-248d of substrate 150 to simplify manufacturing and save cost.

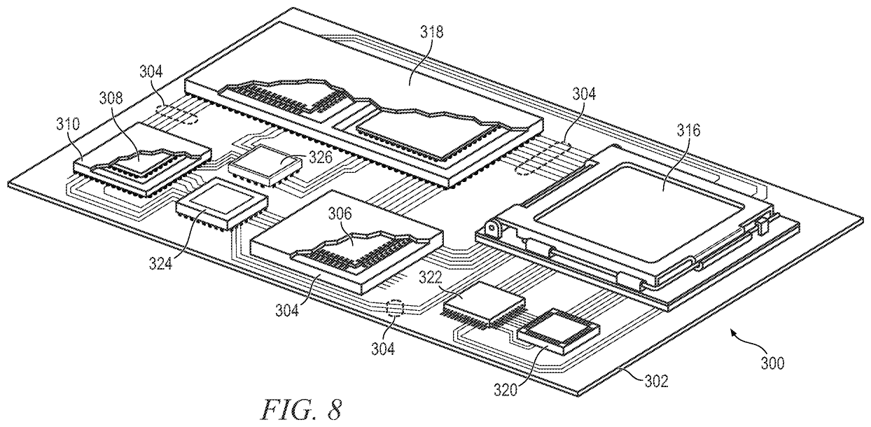

FIG. 8 illustrates electronic device 300 having a chip carrier substrate or PCB 302 with a plurality of semiconductor packages mounted on a surface of PCB 302, including SIP modules 170, 210, and 236. Electronic device 300 can have one type of semiconductor package, or multiple types of semiconductor packages, depending on the application.

Electronic device 300 can be a stand-alone system that uses the semiconductor packages to perform one or more electrical functions. Alternatively, electronic device 300 can be a subcomponent of a larger system. For example, electronic device 300 can be part of a tablet, cellular phone, digital camera, communication system, or other electronic device. Alternatively, electronic device 300 can be a graphics card, network interface card, or other signal processing card that can be inserted into a computer. The semiconductor package can include microprocessors, memories, ASIC, logic circuits, analog circuits, RF circuits, discrete devices, or other semiconductor die or electrical components. Miniaturization and weight reduction are essential for the products to be accepted by the market. The distance between semiconductor devices may be decreased to achieve higher density.

In FIG. 8, PCB 302 provides a general substrate for structural support and electrical interconnect of the semiconductor packages mounted on the PCB. Conductive signal traces 304 are formed over a surface or within layers of PCB 302 using evaporation, electrolytic plating, electroless plating, screen printing, or other suitable metal deposition process. Signal traces 304 provide for electrical communication between each of the semiconductor packages, mounted components, and other external system components. Traces 304 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may only have the first level packaging where the die is mechanically and electrically mounted directly to the PCB. For the purpose of illustration, several types of first level packaging, including bond wire package 306 and flipchip 308, are shown on PCB 302. Additionally, several types of second level packaging, including ball grid array (BGA) 310, bump chip carrier (BCC) 312, land grid array (LGA) 316, multi-chip module (MCM) or SIP module 318, quad flat non-leaded package (QFN) 320, quad flat package 322, embedded wafer level ball grid array (eWLB) 324, and wafer level chip scale package (WLCSP) 326 are shown mounted on PCB 302. In one embodiment, eWLB 324 is a fan-out wafer level package (Fo-WLP) and WLCSP 326 is a fan-in wafer level package (Fi-WLP). Depending upon the system requirements, any combination of semiconductor packages, configured with any combination of first and second level packaging styles, as well as other electronic components, can be connected to PCB 302. In some embodiments, electronic device 300 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using less expensive components and a streamlined manufacturing process. The resulting devices are less likely to fail and less expensive to manufacture resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a first substrate;
disposing a first electrical component over the first substrate; and
disposing a heat spreader over the first electrical component, wherein the heat spreader attaches to the first substrate proximate to a first side of the first electrical component and remains open proximate to a second side of the first electrical component.

2. The method of claim 1, wherein the first electrical component includes:
providing a second substrate;
forming a redistribution layer over the second substrate;
disposing the first electrical component over the redistribution layer; and
disposing the heat spreader over the first electrical component.

3. The method of claim 1, wherein the heat spreader includes:
providing a first horizontal portion;
providing a second horizontal portion vertically offset from the first horizontal portion; and
providing an angled portion connecting the first horizontal portion from the second horizontal portion.

4. The method of claim 3, further including attaching the second horizontal portion of the heat spreader to a surface of the first substrate proximate to a first side of the first electrical component.

5. The method of claim 1, further including attaching the heat spreader to a surface of the first substrate proximate to a first side of the first electrical component, while leaving open from attachment the surface of the first substrate proximate to a second side of the first electrical component.

6. The method of claim 1, further including disposing a second electrical component over the first substrate outside a footprint of the heat spreader.

7. A method of making a semiconductor device, comprising:
providing a first substrate;
disposing a first electrical component over the first substrate; and
disposing a cover over the first electrical component, wherein the cover attaches to the first substrate proximate to a first portion the first electrical component and remains open proximate to a second portion of the first electrical component.

8. The method of claim 7, wherein the cover includes a heat spreader or electromagnetic shielding layer.

9. The method of claim 7, wherein the first electrical component includes:
providing a second substrate;
forming a redistribution layer over the second substrate;
disposing the first electrical component over the redistribution layer; and
disposing the cover over the first electrical component.

10. The method of claim 7, wherein the cover includes:
providing a first horizontal portion;
providing a second horizontal portion vertically offset from the first horizontal portion; and
providing an angled portion connecting the first horizontal portion from the second horizontal portion.

11. The method of claim 10, further including attaching the second horizontal portion of the cover to a surface of the first substrate proximate to a first side of the first electrical component.

12. The method of claim 7, further including attaching the cover spreader to a surface of the first substrate proximate to a first side of the first electrical component, while leaving open from attachment the surface of the first substrate proximate to a second side of the first electrical component.

13. The method of claim 7, further including disposing a second electrical component over the first substrate outside a footprint of the cover.

14. A semiconductor device, comprising:
a first substrate;
a first electrical component disposed over the first substrate; and
a heat spreader disposed over the first electrical component, wherein the heat spreader attaches to the first substrate proximate to a first side of the first electrical component and remains open proximate to a second side of the first electrical component.

15. The semiconductor device of claim 14, wherein the first electrical component includes:
a second substrate;
a redistribution layer formed over the second substrate;
the first electrical component disposed over the redistribution layer; and
the heat spreader disposed over the first electrical component.

16. The semiconductor device of claim 14, wherein the heat spreader includes:
a first horizontal portion;
a second horizontal portion vertically offset from the first horizontal portion; and
an angled portion connecting the first horizontal portion from the second horizontal portion.

17. The semiconductor device of claim 16, wherein the second horizontal portion of the heat spreader is attached to a surface of the first substrate proximate to a first side of the first electrical component.

18. The semiconductor device of claim 14, wherein the heat spreader is attached to a surface of the first substrate proximate to a first side of the first electrical component, while leaving open from attachment the surface of the first substrate proximate to a second side of the first electrical component.

19. The semiconductor device of claim 14, further including a second electrical component disposed over the first substrate outside a footprint of the heat spreader.

20. A semiconductor device, comprising:
a first substrate;
a first electrical component disposed over the first substrate; and
a cover disposed over the first electrical component, wherein the cover attaches to the first substrate proximate to a first portion of the first electrical component and remains open proximate to a second portion of the first electrical component.

21. The semiconductor device of claim 20, wherein the cover includes a heat spreader or electromagnetic shielding layer.

22. The semiconductor device of claim 20, wherein the first electrical component includes:
a second substrate;
a redistribution layer formed over the second substrate;
the first electrical component disposed over the redistribution layer; and
the cover disposed over the first electrical component.

23. The semiconductor device of claim 20, wherein the cover includes:
a first horizontal portion;
a second horizontal portion vertically offset from the first horizontal portion; and
an angled portion connecting the first horizontal portion from the second horizontal portion.

24. The semiconductor device of claim 20, wherein the cover is attached to a surface of the first substrate proximate to a first side of the first electrical component, while leaving open from attachment the surface of the first substrate proximate to a second side of the first electrical component.

25. The semiconductor device of claim 20, further including a second electrical component disposed over the first substrate outside a footprint of the cover.
